(19) United States
(12) Patent Application Publication
(10) Pub. No.: US 2008/0224199 A1
(43) Pub. Date: Sep. 18, 2008

(54) Non-volatile memory module package capability of replacing

(76) Inventors: Li Hui Lu, Chupei (TW); Kun Lin Liu, Chupei (TW); Chih Chieh Ho, Chupei (TW); Jin Xian Lin, Chupei (TW)

Correspondence Address: PRO-TECHTOR INTERNATIONAL SERVICES, 20775 NORADA CT., SARATOGA, CA, 95070, US

(21) Appl. No.: 11/800,134

(22) Filed: May 4, 2007

(30) Foreign Application Priority Data
Mar. 14, 2007 (TW) 096204098

(51) Int. Cl. H01L 29/788

(52) U.S. Cl. 257/314; 257/E29.3

(57) ABSTRACT

A non-volatile memory module package capability of replacing, it may connected to a solid memory module, which includes a control unit, a system interface, and a first connector, the control unit may obtains external signals by the system interface, and then transmitted to this non-volatile memory module by the control unit to store or use the memory content. The package includes a substrate; a second connector is arranged on the substrate for inserting the first connector of the solid memory module; at least a non-volatile memory chip located on the substrate, and electrically connected the substrate and the second connector; at least a passive component is arranged on the substrate; and a compound resin is covered on the non-volatile memory chip and passive component.

### BACKGROUND OF THE INVENTION

1. Field of the Invention

The present invention relates to a non-volatile memory module package capability of replacing, especially a memory capacity one which can plant more than one non-volatile memory module into the presetting connector of solid memory module in order to achieve the purpose of expanding or replacing the non-volatile memory as well as improving the solid memory

2. Description of the Related Art

Since the June, 2006, flash solid state disk (SSD) embedded 32G NAND has be launched, and it was declared that it was the first NAND flash solid state disk deployed for commercial behavior computer application and lifted the curtain on the non-volatile memory replacing the disk. It is described that the slid state disk can bear the twice collision and damage than that of common disk, in addition, when PC is suffered falling and touching or water dipping, it will be easier to bring the storage from the flash memory than the disk. Moreover, the data respeed of solid state disk is 53 Mbps, which is the 3 times than that of common disk; and the write speed is 28 Mbps, which increases 150% than that of the disk. The advantage equipped with this flash solid state disk is that weight of SSD is only half of the common rotating disk. Therefore, this laptop computer with data storage medium will pick up the speed of uploading or downloading data, and the course of processing data is relatively quiet on the ground that SSD uses static NAND quick memory chip which can be able to grasp, and non Winchester disk drive uses the dial, moreover, SSD can save 95% electricity by the Winchester disk drive.

This invention relates to a non-volatile memory module package capability of replacing in order to solve some disadvantages about the study and technology.

### SUMMARY OF THE INVENTION

The objective of this invention is to provide a non-volatile memory module package capability of replacing, it is easily to insert to a solid memory module, so as to effectively expand the solid memory module capacity and make consumers select the memory modules freely as well as enlarge the capacity of solid state disk.

Another objective of this invention is to provide a non-volatile solid memory module package capability of replacing which makes computer facilities select the memory module with specific capacity according to requirements of consumers. Computer manufacturer need not install the non-volatile memory module with large memory capacity beforehand, thus being able to reduce the risks of loss form falling price caused by the memory price fluctuations.

In order to achieve the above objectives, features of this invention, a non-volatile memory module package capability of replacing of the invention, it may connected to a solid memory module, which includes a control unit, a system interface, and a first connector, the control unit may obtains external signals by the system interface, and then transmitted to this non-volatile memory module by the control unit to store or use the memory content, the package includes a substrate; a second connector is arranged on the substrate for inserting the first connector of the solid memory module; at least a non-volatile memory chip is located on the substrate, and electrically connected the substrate and the second connector; at least a passive component is arranged on the substrate; and a compound resin is covered on the non-volatile memory chip and passive component.

Therefore, the purpose of expanding the memory capacity of this invention is to increase the capacity of solid memory module by means of replacing this non-volatile memory module or increase the number of non-volatile memory module.

### BRIEF DESCRIPTION OF THE DRAWINGS

FIG. 1 is a first schematic illustration showing a non-volatile memory module package capability of replacing of the present invention.

FIG. 2 is the second schematic illustration showing a non-volatile memory module package capability of replacing of the present invention.

FIG. 3 is the third schematic illustration showing a non-volatile memory module package capability of replacing of the present invention.

FIG. 4 is the fourth illustration showing a non-volatile memory module package capability of replacing of the present invention.

FIG. 5 is a schematic illustration showing a non-volatile memory module package capability of replacing of the present invention.

### DETAILED DESCRIPTION OF THE INVENTION

In order to explain other features and advantages of this invention and reach more obvious functions, hereby this invention and attached drawings are specified in the following:

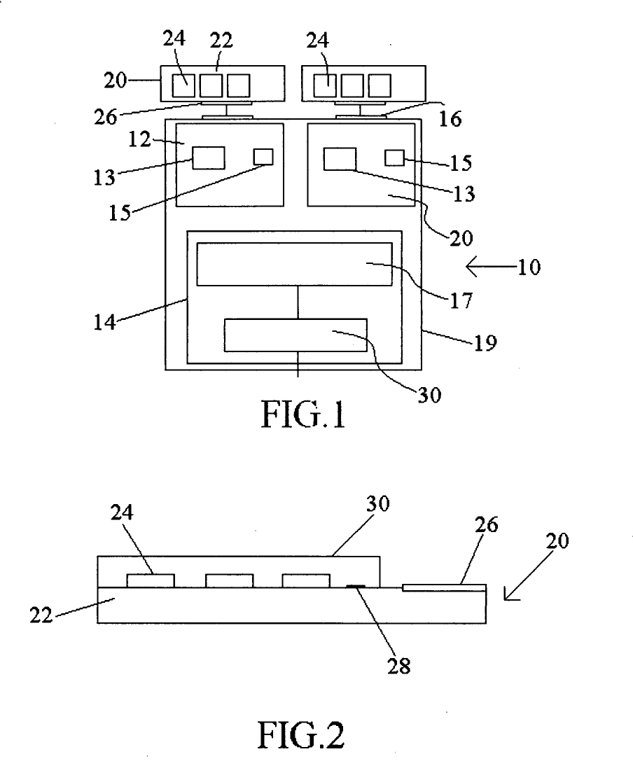

Please refer to FIG. 1. It is the schematic drawing of non-volatile memory module package capability of replacing for inserting a solid memory module 10, which includes a control unit 12, a system interface 14, and a first connector 16. The control unit 12 includes a control chip 13 and a frequency generator 15. The system interface 14 includes an IDE RAID controller and the IDE to SATA conversion chip. The control unit 12 may obtains external signals by the system interface 14, and then transmitted to the non-volatile memory module 10 by the control unit 12 to store or use the memory content.

Please refer to FIG. 2. In the preferred embodiment, the non-volatile memory module package includes a substrate 22, three non-volatile memory chips 24, a second connector 26, at least a passive component 28, and a compound resin 30. Wherein

The three non-volatile memory chips 24 are arranged on the substrate 22, and electrically connected to the substrate 22.

The passive component 28 is located on the substrate 22.

The second connector 26 is arranged on the substrate 22, and electrically connected the each of non-volatile memory chips 24, so that the second connector 26 used for connecting electrically with the first connector 16 of the solid memory module 10, the second connected is made of golden finger.

The component resin 30 is encapsulated on the non-volatile memory chip 24 and passive component 28.

Therefore, the control unit 12 of the solid memory module 10 may obtains external signals by the system interface 14, and then transmitted to this non-volatile memory module by the control unit 12 to store or use the memory content.

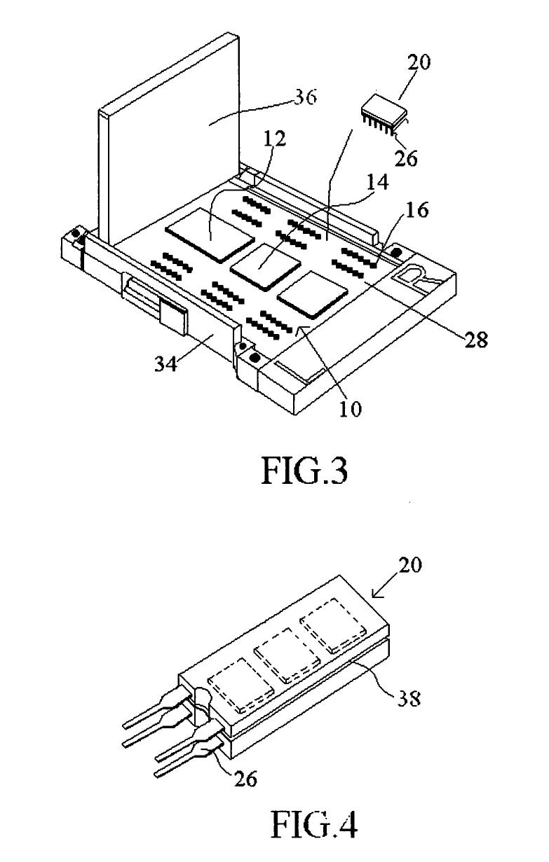

Please refer to FIG. 3. It is a schematic illustration of non-volatile memory module structure of this invention. The first connector 16 of non-volatile memory module 10 is an electrical pin. Please refer to FIG. 3, which is a schematic illustration of non-volatile memory module. The solid memory module 10 is installed within the shell 34 which has an upper cover 36 for opening. The first connector 16 is a slot in the printing circular board 28 used as inserting of the electrical pin of the solid memory module 10 for expanding or replacing its memory capacity.

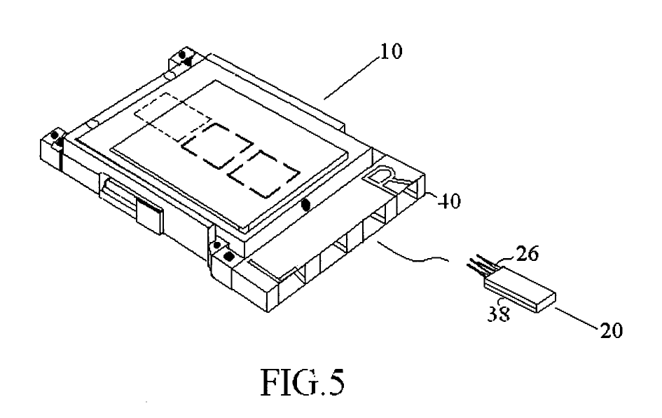

Please refer to FIG. 4. It is another schematic illustration of non-volatile memory module of the invention. The second connector 26 of non-volatile memory module 20 is an electrical pin and both sides of this module have the first sliding chute 38. Please refer to FIG. 5, which is another execution drawing of solid memory module with extensible capacity. The solid memory module 10 is formed with second sliding chute 40, which is electrically connected the first sliding chute.i

From the above discussed, this invention has achieved improvement functions by means of breaking through the prior technology structures and cannot be devised easily by persons who are not familiar with this skill. Moreover, this invention has not been public before application, whose evolutionarity, practicality and novelty have obviously in accordance with the patent application conditions. Therefore, I, with great appreciation, present the invention application in conformity with a law and earnestly request you to examine and approve my application for patent so as to encourage the creation.

The above execution methods are only the technology thoughts and features of this invention in order that persons familiar with this skill can understand the content of this invention and then implement based on it. The patent scope of this invention cannot be limited and still covers the same change or modification revealed according to this invention.

What is claimed is:

1. A non-volatile memory module package capability of replacing, it may connected to a solid memory module, which includes a control unit, a system interface, and a first connector, the control unit may obtains external signals by the system interface, and then transmitted to this non-volatile memory module by the control unit to store or use the memory content, the package comprising;
A substrate;
A second connector arranged on the substrate for inserting the first connector of the solid memory module;
At least a non-volatile memory chip located on the substrate, and electrically connected the substrate and the second connector;
At least a passive component arranged on the substrate; and
A compound resin covered on the non-volatile memory chip and passive component.

2. A non-volatile memory module package capability of replacing, wherein the non-volatile memory chip is the Flash.

3. A non-volatile memory module package capability of replacing according to claim 1, wherein the control unit of the solid memory module includes a control chip and a frequency generator.

4. A non-volatile memory module package capability of replacing according to claim 1, wherein the system interface of the solid memory module includes an IDE RAID controller and the IDE to SATA conversion chip.

5. A non-volatile memory module package capability of replacing according to claim 1, wherein the solid memory module includes a shell within which this solid memory module is installed.

6. A non-volatile memory module package capability of replacing according to claim 5, wherein the shell is equipped with at least one slots, which can make the first connector of this non-volatile memory module inset into this slot, and is electrically connected with the second connector of this solid memory module.

7. A non-volatile memory module package capability of replacing according to claim 6, wherein the slot has the first slider and this non-volatile memory is equipped with the second slider for sliding into this slot.
